(19) United States
(12) Patent Application Publication
(10) Pub. No.: US 2016/0160345 A1
(43) Pub. Date: Jun. 9, 2016

(54) TRANSPARENT CONDUCTIVE FILM

(71) Applicant: NITTO DENKO CORPORATION, Ibaraki-shi, Osaka (JP)

(72) Inventors: Kodai MIYAMOTO, Ibaraki-shi (JP); Kazuaki SASA, Ibaraki-shi (JP); Hironobu MACHINAGA, Ibaraki-shi (JP); Eri UEDA, Ibaraki-shi (JP); Manami KUROSE, Ibaraki-shi (JP); Tomotake NASHIKI, Ibaraki-shi (JP)

(73) Assignee: NITTO DENKO CORPORATION, Ibaraki-shi, Osaka (JP)

(21) Appl. No.: 14/908,855

(22) PCT Filed: May 15, 2015
(86) PCT No.: PCT/JP2015/063996

§ 371 Date: Jan. 29, 2016

(30) Foreign Application Priority Data
May 20, 2014 (JP) 2014-104609

(51) Int. Cl. C23C 14/58; H01B 3/42; H01B 1/02; C23C 14/08; C23C 14/35

(52) U.S. Cl. CPC C23C 14/58; C23C 14/086; C23C 14/35; H01B 1/02; H01B 3/426; H01B 3/427

(57) ABSTRACT

Provided is a transparent conductive film that can drastically improving an electrical characteristic of a transparent conductive layer after crystallizing process with resped to the transparent conductive layer before the crystallizing process and can achieve a lower resistivity.

The transparent conductive film (1) is provided with a film substrate (2) and a crystalline transparent conductive layer (3) formed on one of the main surfaces (2a) of the said substrate. The amorphous transparent conductive layer before the crystallizing process has a carrier density nₐ×10¹⁹ of (10 to 60)×10¹⁹/cm³ and Hall mobility μₐ of 10 to 25 cm²/V·s, the crystalline transparent conductive layer after the crystallizing process has a carrier density n_{c}×10¹⁹ of (80 to 150)×10¹⁹/cm³ and Hall mobility t of 20 to 40 cm²/V·s, and the length of motion L defined by {(n_{c}−nₐ)²+(μ_{c}−μₐ)²}^{1/2} is 50 to 150.

### TECHNICAL FIELD

The present invention relates to a transparent conductive film applicable to an input display unit capable of inputting information by a touch of a finger, a stylus pen, or the like.

### BACKGROUND ART

In the related art, touch panel sensors of a capacitive type includes a transparent conductive film having a film substrate, a transparent conductive layer provided on a surface of the film substrate, and an adhesive layer laminated to embed the transparent conductive layer. Generally, a transparent electrode pattern is obtained by forming a film of ITO (indium tin oxide) on a substrate by sputtering, thereafter performing a crystallizing process by heating on the film, and performing an etching process or the like on the ITO film after the heating.

Recently, there is an increasing demand for employing such a transparent conductive film in capacitive touch panel sensors capable of sensing multi-point input (multi-touch). Also, in order to obtain large-sized screens and to improve the response speed, there is a demand for a further improvement in transparent conductive films.

For example, a transparent conductive film is proposed which is provided with a transparent conductive layer composed of an indium-tin. composite oxide in which an amount of tin atoms is 1% to 6% by weight with respect to the summed weight of indium atoms and tin atoms, the transparent conductive layer haying a film thickness of 15 to 50 nm, Hall mobility of 30 to 45 cm²/V·s, and a carrier density of (2 to 6)×10²⁰/cm³ (patent document 1). With this transparent conductive layer, the Hall mobility is 15 to 28 cm²/V·s and the carrier density is (2 to 5)×10²⁰/cm³ before the crystallizing process by heating. Accordingly, the Hall mobility after the crystallizing process by heating takes a value greater than that of the Hall mobility before the crystallizing process by heating, and the carrier density after the crystallizing process by heating is almost the same as the carrier density before the crystallizing process by heating. According to the present configuration, a crystalline transparent conductive layer is provided that has a good transparency and a specific resistance that is not too low.

As another transparent conductive film, a transparent conductive film is proposed in which a surface of a transparent substrate on a side a transparent conductive layer is formed has an arithmetic average roughness Ra of less than or equal to 1.0 nm, an amount of tin atoms in the transparent conductive layer is greater than 6% by weight and less than or equal to 15 by weight with respect to the summed weight of indium atoms and tin atoms, the transparent conductive layer has Hall mobility of 10 cm²/V·s to 35 cm²/V·s and a carrier density of (6 to 15)×10²⁰/cm³ (patent document 2). With this transparent conductive layer, Hall mobility is 5 cm²/V·s to 30 cm²/V·s and a carrier density is (1 to 10)×10²⁰/cm³ before the crystallizing process by heating. Accordingly, each of Hall mobility and a carrier density after the crystallizing process by heating has a value that is somewhat greater than a value before the crystallizing process.

### DOCUMENT LIST

### Patent Document(s)

Patent Document 1: Japanese Laid-Open Patent Publication No. 2006-202756
Patent Document 2 Japanese Laid-Open Patent Publication No. 2012-134085

### SUMMARY OF INVENTION

### Technical Problem

However, the transparent conductive film includes the substrate formed of a polymer, and thus it is not possible to heat the ITO transparent conductive layer at a high temperature for a long period of time during the crystallizing process by heating. Accordingly, there is a limitation to an amount of tin to be substituted in the ITO transparent conductive layer, and thus there is a problem that it is difficult to achieve a lower resistivity.

It is an object of the present invention to provide a transparent conductive film that has a drastically improved electrical characteristic of the transparent conductive layer after the crystallizing process by heating an amorphous transparent conductive layer before the crystallizing process and can achieve a lower resistivity.

### Solution to Problem

In order to solve the aforementioned problem, a transparent conductive film of the present invention is a transparent conductive film comprising a crystalline transparent conductive layer, the crystalline transparent conductive layer being Obtained by forming an amorphous transparent conductive layer on a polymeric film substrate by sputtering, the amorphous transparent conductive layer being composed of an indium-tin. complex oxide, and performing a crystallizing process on the amorphous transparent conductive layer, characterized in that, defining that the amorphous transparent conductive layer has a carrier density represented by nₐ×10¹⁹ and Hall mobility represented by μₐ, the crystalline transparent conductive layer has a carrier density represented by n_{c}×10¹⁹ and Hall mobility represented by μ_{c}; and a length of motion L represented by {(n_{c}−nₐ)²+(μ_{c}−μₐ)²}^{1/2}, the amorphous transparent conductive layer before the crystallizing process has a carrier density nₐ×10¹⁹ of (10 to 60)×10¹⁹/cm³ and Hall mobility μₐ of 10 to 25 cm²/V·s, the crystalline transparent conductive layer after the crystallizing process has a carrier density n_{c}×10¹⁹ of (80 to 150)×10¹⁹/cm³ and Hall mobility μ_{c} of 20 to 40 cm²/V·s, and the length of motion L is 50 to 150.

The crystallizing process is a process of crystallizing the amorphous transparent conductive layer at a temperature of 110 to 180° C. within 120 minutes.

Further, the amorphous transparent conductive layer has a thickness of 10 nm to 40 nm; the amorphous transparent conductive layer has a specific resistance of 4.0×10⁻⁴ Ω·cm to 2.0×10⁻³ Ω·cm and the crystalline transparent conductive layer has a specific resistance of 1.1×10⁻⁴ Ω·cm to 3.0×10⁻⁴ Ω·cm.

Further, the crystalline transparent conductive layer is composed of an indium-tin composite oxide; and a ratio of tin oxide represented by {tin oxide/(indium oxide+tin oxide)}×100 (%) is 0.5% to 15% by weight.

### Effects of Invention

According to the present invention, since {(n_{c}−nₐ)²+(μ_{c}−μₐ)²}^{1/2} calculated from Hall mobility and a carrier density before the crystallizing process and Hall mobility and a carrier density after the crystallizing process is defined as a length of motion L, and the length of motion is 50 to 150, an electrical characteristic of the crystalline transparent conductive layer after the crystallizing process with respect to the amorphous transparent conductive layer before the crystallizing process drastically improves, and a lower resistivity can be achieved.

Further, since the amorphous transparent conductive layer is crystallized at a temperature of 110 to 180° C. for less than or equal to 2 hours, crystallization can be performed at a relatively low temperature over a short time, and thus the crystalline transparent conductive layer can be formed efficiently.

Further, since the amorphous transparent conductive layer has a thickness of 15 nm to 40 nm, the amorphous transparent conductive layer has a specific resistance of 4.0×10⁻⁴ Ω·cm to 2.0×10⁻³ Ω·cm, and the crystalline transparent conductive layer has a specific resistance of 1.1×10⁻⁴ Ω·cm to 3.0×10⁻⁴ Ω·cm, it is possible to achieve a lower resistivity while maintaining transparency and anti-flexing characteristics.

Further, in the present invention, the crystalline transparent conductive layer is composed of an indium-tin composite oxide, and a ratio of tin oxide represented by {tin oxide/(indium oxide+tin oxide)}×100 (%) is 0.5% to 15% by weight. That is, even in a case where crystallization is difficult due to a large amount of tin atoms, the present invention ensures crystallization of the amorphous transparent conductive layer and a lower resistivity can be ensured.

### BRIEF DESCRIPTION OF DRAWINGS

FIG. 1 is a cross sectional view schematically showing a configuration of a transparent conductive film according to an embodiment of the present invention.

FIG. 2 is a cross sectional view showing a variant of the transparent conductive film according to the embodiment of the present invention.

FIG. 3 is a diagram showing lengths of motion in transparent conductive layers of Examples 1 to 7.

FIG. 4 is a diagram showing lengths of motion in transparent conductive layers of Comparative Examples 1 to 3.

### DESCRIPTION OF THE PREFERRED EMBODIMENTS

Hereinafter, preferred embodiments of the present invention will he described in detail with reference to the attached drawings.

FIG. 1 is a drawing schematically showing a configuration of a transparent conductive film according to the present embodiment. The length, the width and the thickness of each constituent element in FIG. 1 are shown by way of example, and the length, the width and the thickness of each constituent element in a touch panel sensor of the present invention are not limited to those illustrated in FIG. 1.

As illustrated in FIG. 1, a transparent conductive film 1 includes a film substrate 2 and a crystalline transparent conductive layer 3 provided on one of the main surfaces 2a of the substrate. A dielectric layer or an undercoat layer such as a hard coat layer may be provided between the film substrate 2 and the crystalline transparent conductive layer 3. Further, an adhesive layer may be provided on the crystalline transparent conductive layer 3.

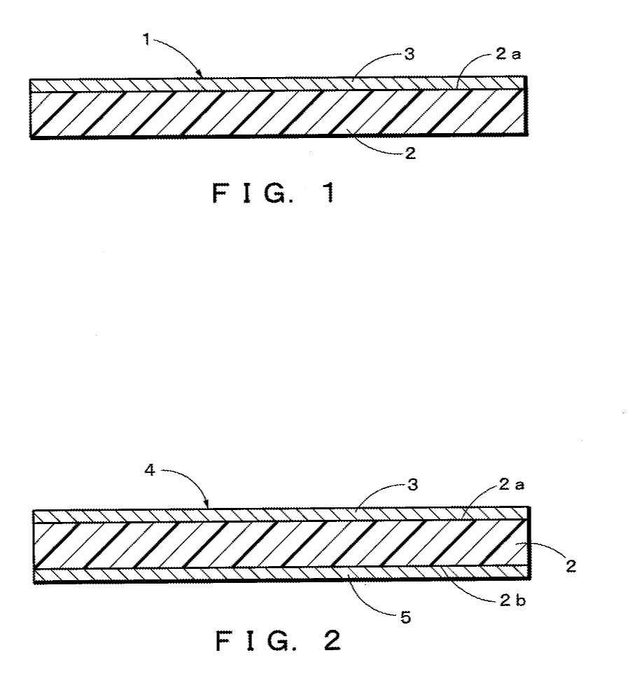

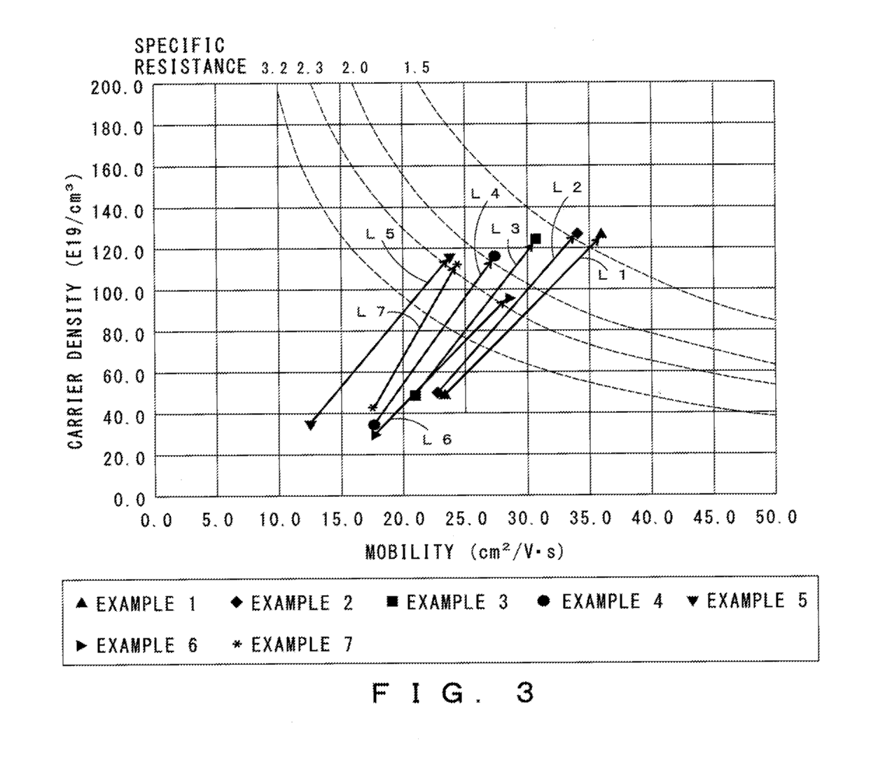

According to the present embodiment, the transparent conductive film 1 includes the crystalline transparent conductive layer 3 provided on one of the main surfaces a2 of the film substrate 2. However, as shown in FIG. 2, a transparent conductive film 4 may include crystalline transparent conductive layers 3 and 5 that are respectively provided on the main surfaces 2a and 2b of the film substrate 2. In other words, the crystalline transparent conductive layer of the present invention may he provided on both sides of the film substrate.

Each component of the transparent conductive film 1 of the present invention will now be described in detail.

(1) Film Substrate

The film substrate 2 is a polymeric film having a strength necessary for ease of handling and transparency in a visible light range. As a polymeric film, it is preferable to use a film having an improved transparency, heat resistance, and surface smoothness, which may be formed of a material such as a polymer composed of a single type of component among polyesters such as polyethylene terephthalate or polyethylenenaphthalate, polycycloolefin, and polycarbonate, or a copolymer composed of one of the above components and another component. Specifically, polyethylene terephthalate (PET), polyethylenenaphthalate (PEN), polycycloolefin and polycarbonate are particularly preferable due to their good transparency and mechanical characteristics. Also, regarding the strength, it is preferable that the polymeric film is subjected to a stretching process and more preferably subjected to a biaxially oriented stretching process. The stretching process is not particularly limited, and a known stretching process may be employed. The thickness of the substrate is not particularly limited, but it is preferably within a range of 2 μm to 200 μm, more preferably within a range of 2 μm to 150 μm and further preferably within a range of 20 μm to 150 μm. When the thickness of the film is less than 2 μm, there may be a case where the mechanical strength is insufficient, which makes it difficult to perform an operation of continuously forming an amorphous transparent conductive layer with the film in a roll shape. On the other hand, when the thickness of the film exceeds 200 μm, there may be a case where an anti-scratch property of the crystalline transparent conductive layer or a touch point characteristic for a case where a touch panel is formed cannot be improved.

(2) Crystalline Transparent Conductive Film

The crystalline transparent conductive layer is obtained by performing, under a predetermined condition, a crystallizing process by heating on an amorphous transparent conductive layer provided on the film substrate. At least one of the crystalline transparent conductive layers include a predetermined transparent conductor, and the transparent conductor is formed of a material that is preferably a metal oxide of at least one kind of metals selected from a group consisting of In, Sn, Zn, Ga, Sb, Ti, Si, Zr, Mg, Al, Au, Ag, Cu, Pd and W, but not particularly limited thereto. The metal oxide may further include metal atoms indicated in the aforementioned group as needed. For example, it is preferable to use indium-tin composite oxide (ITO), antimony-tin composite oxide (ATO), or the like, and it is particularly preferable to use ITO.

In a case where ITO (In₂O₃—SnO₂ metal oxide) is used as a constituent material of the crystalline transparent conductive layer, an amount of SnO₂ in the metal oxide is preferably 0.5% by weight to 15% by weight with respect to an added weight of In₂O₃ and SnO₂, and preferably 3% to 15% by weight, more preferably 5% to 12% by weight, and further preferably 6% to 12% by weight. In a case where the content of tin atoms in the crystalline transparent conductive layer is less than 0.5% by weight, there is a small amount of tin atoms that can be substituted, and thus the carrier density becomes small. As a result, the specific resistance becomes high. In a case where the content of tin atoms is greater than 15% by weight, there is an increased amount of tin atoms that do not contribute to substitution, and thus the mobility becomes small and the specific resistance becomes high.

The ITO layer may also include a metal element other than In or Sn, and at least one kind of metal selected from a group consisting of Zn, Ga, Sb, Ti, Zr, Mg, Al, Au, Ag, Cu, Pd, W, Fe, Pb, Ni, Nb, Cr, and Ga may be included by less than 3% by weight.

The crystalline transparent conductive layer may have a structure in which a plurality of indium-tin composite oxide layers having mutually different amount of tin are laminated. In this case, there may be two ITO layers or three or more ITO layers. In a case where there are two or more 110 layers, at least one of the layers is a crystalline transparent conductive laver, and preferably, all layers are crystalline transparent conductive layers.

In a case where the crystalline transparent conductive layer is formed with two ITO layers, an amount of SnO₂ in a first ITO layer on a film substrate side with respect to an added weight of In₂O₃ and SnO₂ is preferably 6% by weight to 15% by weight, more preferably 6% to 12% by weight, and further preferably 6.5% to 10.5% by weight. An amount of SnO₂ in a second ITO layer with respect to the t weight of In₂O₃ and SnO₂ is preferably 0.5% by weight to 5.5% by weight, more preferably 1% to 5.5% by weight, and further preferably 1% to 5% by weight. By making an amount of tin in each ITO layer to be within the abovementioned ranges, an amorphous transparent conductive layer having a small specific resistance and a short crystallization time by heating can be formed.

Typically, an indium-based composite oxide is used as a transparent conductive thin film. This is to make use of the fact that, with an oxide of a tetravalent metal element being introduced into indium oxide, substitution occurs between trivalent indium and a tetravalent metal element when forming crystals of indium oxide by, for example, heating, and excess electrons serve as carriers in a crystalline layer. Therefore, in a case where the content of oxide of a tetravalent metal element is increased in an indium-based composite oxide, a specific resistance decreases due to an increase in carriers serving as an electric current.

On the other hand, concerning the crystallization of the indium oxide, an increase in the content of an oxide of tetravalent metal element causes an increase in impurities that inhibit crystallization. Accordingly, under the same heating temperature, crystallization takes a longer crystallization time as the content of an oxide of tetravalent metal element becomes greater. Further, it is considered that crystallization of indium oxide can be performed with a shorter crystallization time if crystal nuclei can he formed at a lower energy. In other words, ensuring energy necessary for forming crystal nuclei is a rate-limiting factor for the crystallization described above.

Also, since a thin film of indium oxide formed on the film substrate is influenced by gas produced from the film substrate during sputtering, it is assumed that a thin film formed at a position far from the film substrate (the outermost side) is less defective and easier to crystallize.

Therefore, according to the present invention, when forming a transparent conductive layer having a double-layered structure, a first indium-tin composite oxide layer haying a greater percentage of an SnO₂ weight in the ITO layer is provided on a film substrate side, and next, a second indium-tin composite oxide layer having a smaller percentage of an SnO₂ weight in the ITO layer is provided, and a layer having a smaller percentage of impurity such as tetravalent metal elements and easier to crystallize is located at an outermost side (a side in contact with ambient air). By employing such a structure, crystallization time of the amorphous transparence conductive layer can be shortened and a specific resistance of the crystalline transparent conductive layer as a whole can be decreased.

In a case where the crystalline transparent conductive layer is formed of three ITO layers, an amount of SnO₂ in a first ITO layer on a film substrate side with respect to the added weight of In₂O₃ and SnO₂ is preferably 0.5% by weight to 5.5% by weight, more preferably 1% to 4% by weight, and further preferably 2% to 4% by weight. Also, an amount of SnO₂ in the second ITO layer formed adjacently on the first ITO layer with respect to the added weight of In₂O₃ and SnO₂ is preferably 6% by weight to 15% by weight, more preferably 7% to 12% by weight, and further preferably 8% to 12% by weight. Also, the amount of SnO₂ in the third ITO layer formed adjacently on the second ITO layer with respect to the added weight of In₂O₃ and SnO₂ is preferably 0.5% by weight to 5_5% by weight, more preferably 1% to 4% by weight, and further preferably 2% to 4% by weight. By making an amount of tin in each ITO layer to be within the abovementioned ranges, a crystalline transparent conductive layer having a small specific resistance can be formed.

When forming a transparent conductive layer of a triple-layered structure, a first indium-tin composite oxide layer having a smaller percentage of an amount of SnO₂ in the ITO layer is provided on the film substrate side, and thus, during sputtering, an influence of gas produced from the film substrate can be reduced and inhibiting of the crystallization of the amorphous transparent conductive layer can be suppressed. Further, by providing a third indium-tin composite oxide layer having a smaller percentage of an amount of SnO₂ in the ITO layer at an outermost side, time taken until crystallization of the transparent conductive film begins can be shortened. As a result, crystallization of the amorphous transparent conductive layer as a whole including the second indium-tin composite oxide layer is accelerated, and thus the crystallization time of the amorphous transparence conductive layer is further shortened and the specific resistance of the crystalline transparent conductive layer as a whole can be decreased.

The crystalline transparent conductive layer having the aforementioned single-layered or multi-layered structure has a thickness of 15 nm to 40 nm, and preferably 15 nm to 35 nm. In a case where the thickness is less than 15 nm, it becomes difficult to crystallize in the crystallization process by heating, and in a case where the thickness is greater than 40 nm, transparency and flexibility will decrease.

It is preferable that the crystalline transparent conductive layer is crystallized by the crystallizing process by heating. Whether the crystalline transparent conductive layer has crystallized can be determined by immersing the crystalline transparent conductive layer in dilute hydrochloric acid of concentration 5% by weight for 15 minutes, thereafter washing with water and drying, and measuring the resistance between terminals at an interval of 15 mm. Herein, it is determined that crystallization of the ITO layer into crystalline has been completed, when the resistance between the terminals at an interval of 15 mm is not excessive of 10 kΩ after immersing in hydrochloric acid, rinsing with water and drying.

The aforementioned crystalline transparent conductive layer may be patterned by etching into any geometry, such as a comb shape, a striped shape, and a diamond shape, depending on application. For example, it is preferable that the crystalline transparent conductive layer is patterned into a stripe shape for a transparent conductor used in touch panels of a capacitive sensing type or touch panels of a matrix resistive film type. In a case where etching is used for patterning the crystalline transparent conductive layer, there may be a case where patterning by etching becomes difficult if it is preceded by crystallization of the amorphous transparent conductive layer. Therefore, the crystallizing process by heating for the crystalline transparent conductive layer may be performed after having patterned the amorphous transparent conductive layer.

(Undercoat Layer)

An undercoat layer such as a dielectric layer or a hard coat layer may be provided between the film substrate 2 and the crystalline transparent conductive layer 3. Among them, the dielectric layer provided on a surface of the film substrate 2 at a side of a face on which a crystalline transparent conductive layer is formed does not serve as an electrically conducting layer, and has a surface resistance of, for example, greater than or equal to 1×10⁶ Ω/□ (unit: ohms per square), preferably greater than or equal to 1×10⁷ Ω/□, and further preferably greater than or equal to 1×10⁸ Ω/□. Note that there is no particular upper limit to the surface resistance of the dielectric laver. Typically, an upper limit to the surface resistance of the dielectric layer is about 1×10¹³ Ω/□ which is a limit of measurement, but may exceed 1×10¹³ Ω/□.

The material of the dielectric layer includes an inorganic material such as NaF (1.3), Na₃AlF₆ (1.35), LiF (1.36), MgF₂ (1.38), CaF₂ (1.4), BaF₂ (1.3), BaF₂ (1.3), SiO₂ (1.46). LaF₃ (1.55), CeF (1.63), Al₂O₃ (1.63) [numerical values in parentheses indicate refractive indices], an organic material having a refractive index of about 1.4 to 1.6 such as an acrylic resin, an urethane resin, a melamine resin, an alkyd resin, a siloxane-based polymer, and an organosilane condensate, or a mixture of the above-mentioned organic material and the above-mentioned inorganic material.

(Organic Dielectric Layer)

It is preferable that an organic dielectric layer formed of the above-mentioned organic material or a mixture of the above-mentioned inorganic material and the organic material is formed on the film substrate by a wet film formation method (e.g., gravure coating method). By wet coating, surface roughness of the film substrate can be decreased and can contribute to a decrease in specific resistance. The thickness of the organic dielectric layer can he determined as appropriate within a preferable range, and it is preferably 15 nm to 1500 nm, more preferably 20 nm to 1000 nm, and further preferably 20 nm to 800 nm, Within the above-mentioned range, the surface roughness can he sufficiently suppressed. The organic dielectric layer may he a laminate of a plurality of layers of two or more different kinds of the above-mentioned organic materials having refractive indices differing by 0.01 or more or a mixture of the above-mentioned inorganic material and the above-mentioned organic material.

In order to obtain a good transparent conductive layer, it is preferable that a surface of the film substrate is smooth. It is presumed that the growth of crystal grains is inhibited if the surface of the film substrate is rough. By forming a transparent conductive layer on a smooth film substrate, it is possible to grow large crystal grains, and thus scattering of a carrier by a grain boundary of the crystal grain can be decreased and mobility can be increased. The value of a preferred arithmetic mean roughness (Ra) of a surface of the film substrate is less than or equal to 1.5 nm.

A method of smoothing the surface of the film substrate may be, for example, a method of forming, on a film substrate, a coating layer as the organic dielectric layer. The coating layer may be formed by applying and curing a solution of a thermosetting resin or an ultraviolet-curable resin on the substrate. The type of resin is not particularly limited, but may be an epoxy-based resin or an acrylic resin.

(Inorganic Dielectric Layer)

It is preferable that an inorganic dielectric layer formed of the aforementioned inorganic material is formed on the film substrate 2 by a vacuum film formation method (e.g., a sputtering method and a vacuum deposition method). By forming an inorganic dielectric layer having a high density by a vacuum film formation method, water an impurity gas such as an organic gas released from the polymeric film substrate can be suppressed when forming the amorphous transparent conductive layer 3 by sputtering. As a result, an amount of impurity gas introduced into the amorphous transparent conductive layer can he decreased, which contributes to suppression of the specific resistance after the crystallization. The thickness of the inorganic dielectric layer is preferably 2.5 nm to 100 nm, more preferably 3 nm to 50 nm, and further preferably 4 nm to 30 nm. Within the aforementioned range, the release of an impurity gas can be sufficiently suppressed. Also, the inorganic dielectric layer may include a plurality of laminated layers of two or more kinds of the above-mentioned inorganic materials having refractive indices differing by 0.01 or more

Also, by providing, on the polymeric substrate film, a film formed by a physical vapor phase growth (PVD) method as the above-mentioned inorganic dielectric layer, a resin component or water contained in the polymeric substrate film and diffused during the sputter film formation process can be inhibited from being introduced into the transparent conductive layer, which can contribute to an improvement in the mobility and the carrier density. As a physical vapor phase growth (PVD) method, sputtering is preferable.

It is preferable that the material of the film formed by a physical vapor phase growth (PVD) method is a metal oxide such as aluminum oxide or silicon oxide. It is preferable that the thickness of the film formed by a physical vapor phase growth (PVD) method is 20 nm to 100 nm.

Also, the dielectric layer may be a combination of the organic dielectric layer and the inorganic dielectric layer. By combining the organic dielectric layer and the inorganic dielectric layer, a substrate having a smooth surface and capable of inhibiting an impurity gas during sputtering is obtained, and the specific resistance of the crystalline transparent conductive layer can he reduced effectively. The thickness of each of the organic dielectric layer and the inorganic dielectric layer can be determined as appropriate within the ranges described above.

As described above, by forming a dielectric layer on the film substrate at a side on which a crystalline transparent conductive layer is formed, in a case where, for example, the crystalline transparent conductive layer 3 is patterned into a plurality of transparent electrodes, it is possible to decrease the difference in visibility between a crystalline transparent conductive layer formation region and a crystalline transparent conductive layer absent region. Also, when a film substrate is used, a dielectric layer may also serve as a confinement layer that confines precipitation of a low molecular weight component such as oligomers, from the polymeric film.

(3) Amorphous Transparent Conductive Layer Before the Crystallizing Process Has a Carrier Density nₐ×10¹⁹ of (10 to 60)×10¹⁹/cm³ and Hall Mobility μₐ of 10 to 25 cm²/V·s

Defining that the amorphous transparent conductive layer immediately after sputtering (as-deposited) and before the crystallizing process has a carrier density represented by na and Hall mobility represented by μₐ, the carrier density nₐ×10¹⁹ is (10 to 60)×10¹⁹/cm³ and Hall mobility μₐ is 10 to 25 cm²/V·s. Also, the amorphous transparent conductive layer has a thickness of 15 nm to 40 nm, arid the amorphous transparent conductive layer has a specific resistance of 4.0×10⁻⁶ Ω·cm to 2.0×10⁻³ Ω·cm.

(4) Crystalline Transparent Conductive Layer After the Crystallizing Process by Heating Has a Carrier Density n_{c}×10¹⁹ of (80 to 150)×10¹⁹/cm³ and Hail Mobility μ_{c} of 20 to 40 cm²/V·s

Defining that the crystalline transparent conductive layer after the crystallizing process by heating has a carrier density represented by n_{c} and Hall mobility represented by μ_{c}, the carrier density n_{c}×10¹⁹ is (80 to 150)×10¹⁹/cm³ and Hall mobility μ_{c} is 20 to 40 cm²/V·s. Also, the specific resistance of this crystalline transparent conductive layer is 1.1×10⁻⁴ Ω·cm to 3.0×10⁻⁴ Ω·cm.

(5) Length of Motion L being 50 to 150

According to the present invention, a length of motion L of the transparent conductive layer is defined as a left-hand-side of an equation expressed by:

L={(n_{c}−nₐ)²+(μ_{c}−μₐ)²}^{1/2},

where the amorphous transparent conductive layer has a carrier density represented by nₐ×10¹⁹ and Hall mobility represented by μₐ, the crystalline transparent conductive layer has a carrier density represented by n_{c}×10¹⁹ and Hall mobility represented by μ_{c}. The length of motion L is 50 to 150, and preferably 65 to 150. In a case where the length of motion L is less than 50, the resistance is not sufficiently low. For the length of motion L to exceed 150, it is necessary to perform the crystallizing process at a high temperature of 180° C. or higher, or a crystallizing process over a long time for 120 minutes or longer, which is difficult to achieve with a polymeric film substrate.

(6) Method of Manufacturing a Transparent Conductive Film

A method of manufacturing the transparent conductive film configured as above will now be described. Note that the manufacturing method described below given by way of example, and the method of manufacturing the transparent conductive film according to the present invention is not limited thereto.

First, a chamber of a sputtering equipment is depressurized until it comes to a high vacuum, and an inert gas such as an argon gas is introduced into the chamber, Then, an initial roll obtained by winding a film substrate is placed in a sputtering equipment, and a long film-shaped film substrate is delivered at a constant rate from the initial roll into the chamber.

Then, on one of the surfaces of the film substrate, an amorphous transparent conductive layer of an indium tin composite oxide is formed by sputtering. As a method of sputtering, a DC magnetron sputtering method or a RF superposition DC magnetron sputtering method may be employed, and damages on the film substrate can be suppressed by forming a magnetic field on a target surface to confine electrons. Also, by applying a voltage obtained by superimposing a high frequency and a direct current to a target, an argon ion energy can be controlled and a discharge voltage can be lowered. The discharge voltage while forming the amorphous transparent conductive layer is 20 V to 420 V, and preferably 100 V to 200 V. A horizontal magnetic field while forming the amorphous transparent conductive layer is 30 mT to 200 mT, and preferably 80 mT to 130 mT.

(RF Superposition)

By superimposing RF (high frequency) on a DC voltage source while sputtering, a density of plasma to be produced increases, and with an increase in plasma density, ionization efficiency of sputter particles (such as argon) increases. By increasing the ionization efficiency, a transparent conductive film can be formed under a low-voltage and high-current condition.

By performing the sputtering at a low voltage, energy acquired by neutral argon atoms or O₂⁻ ions in an atmosphere can he decreased. Thus the speed of the neutral argon atoms or O₂⁻ ions which have bombarded on the target and recoiled can be decreased, and collision of the neutral argon atoms or O₂⁻ ions onto e transparent conductive layer thus formed can be suppressed, If the recoiled Ar atoms or O₂⁻ ions collide the transparent conductive layer, defects may occur in a film, or particles which have collided will be introduced into the film as impurities, and will do damage to the film. A defect in a thin film and an impurity atom that is introduced will be a center of scattering of a carrier, and becomes a factor of disturbing the electron transfer.

However, it is possible to decrease an occurrence of a defect in the film or introduction of impurities caused by particles recoiled by sputtering at a low voltage, and improvement of the mobility can be achieved.

Also, with an increased ionization efficiency, when converting an amorphous film formed by superimposing RFs into crystalline, an amount of Sin oxide which cannot be substituted can be decreased. Oxide of Sn that does not contribute to substitution is not capable of producing a carrier and may also become a neutral scattering center. However, with an increase in an ionization efficiency, it is possible to decrease production of the scattering centers and to increase mobility and a carrier density.

Also, in a case where RF superposition is performed, a floating potential increases. However, when the floating potential becomes too high, Ar+ ions existing in the vicinity of the film substrate is accelerated due to a potential difference between the floating potential and the substrate potential, and collide the thin film and do damage on the film. Accordingly, a power ratio of RF to DC is preferably 0.05 and 1.5, and more preferably around 0.8.

(High Magnetic Field)

Furthermore, when a magnetic field is increased in a direction parallel to the film substrate to be formed, more electrons will be captured in the vicinity of the target. Accordingly, ionization efficiency improves, and sputtering at a lower voltage and a higher current can be performed.

Also, while forming the amorphous transparent conductive layer, the temperature of the film substrate is −10° C. or higher, and preferably 100° C. or higher. With the temperature of the film substrate being 130° C. or higher, even if an amorphous transparent conductive layer having a relatively high content of tin atoms is used, crystallization of the amorphous transparent conductive layer is likely to be accelerated in a crystallizing process by heating. Accordingly, a crystalline transparent conductive layer having a low resistance can be obtained.

The content of tin or tin oxide in the amorphous transparent conductive layer is substantially the same as the content of tin or tin oxide in a sintered target placed in the sputtering equipment, and thus can be adjusted by varying the content of tin or tin oxide in the sintered target. Also, the thickness of the amorphous transparent conductive layer can be adjusted as appropriate by varying a transportation speed of an elongated film substrate, or increasing or decreasing the number of target materials. Also, by placing a plurality of targets of different contents of tin or tin oxide, a plurality of amorphous transparent conductive layers with different contents of tin or tin oxide can be laminated.

Then, the elongated film substrate on which an amorphous transparent conductive layer is formed is continuously conveyed into a heating oven, and a crystallizing process by heating is performed. The heating temperature of the crystallizing process is 110 to 180° C., and preferably 110 to 150° C. Also, an annealing time is within 120 minutes, and preferably within 60 minutes. With this process, the amorphous transparent conductive layer is crystallized, and a crystalline transparent conductive layer is formed on the film substrate.

In the transparent conductive film produced by the above-mentioned method, the carrier density of the crystalline transparent conductive layer after the crystallizing process by heating is greater than the carrier density before the crystallizing process, and Hall mobility also increases. Specifically, with respect to the carrier density before the crystallizing process nₐ×10¹⁹ of (10 to 60)×10¹⁹/cm³, the carrier density after the crystallizing process n_{c}×10¹⁹ is largely increased to (80 to 150)×10¹⁹/cm³. Also, with respect to the Hall mobility before the crystallizing process μₐ of 10 to 25 cm²/V·s, the Hall mobility after the crystallizing process μ_{c} is largely increased to 20 to 40 cm²/V·s. Also, according to the present invention, a length of motion L calculated using the values of the carrier density nₐ×10¹⁹, n_{c}×10 and the Hall mobility μₐ and μ_{c} is defined as a new index, and with the length of motion L being 50 to 150, an electric characteristic of the crystalline transparent conductive layer with respect to that of the amorphous transparent conductive layer drastically improves, and a lower resistivity can be achieved as compared to the related art. Also, even in a case where the content of tin atoms is relatively high, the amorphous transparent conductive layer can he crystallized at a temperature of 110 to 180° C. within 120 minutes. Accordingly, as compared to the related art, a crystalline transparent conductive layer having an improved transparency can be formed efficiently and productivity can he improved.

In the above description, a touch panel sensor according to the present embodiment has been described, but the present invention is not limited to an embodiment of described above, and various modification and alteration can he made based on a technical idea of the present invention.

### EXAMPLES

Hereinafter, examples of the present invention will he described.

### Example 1

On one of the faces of a substrate formed of a PET film having a thickness of 50 μm (manufactured by Mitsubishi Plastics Industries, product name “DIAFOIL”), a thermoset resin (organic dielectric layer) having a thickness of 35 nm was formed to provide a film substrate. The film substrate was placed in a vacuum sputtering equipment, and the vacuum sputtering equipment was sufficiently evacuated until the degree of vacuum reaches 1×10⁻⁴ Pa or less. Then, using a DC magnetron sputtering method, an inorganic dielectric layer composed of Al₂O₃ and having a thickness of 5 nm was formed on the organic dielectric layer. Then, under a vacuum atmosphere (0.40 Pa) in which Ar and O₂ (a flow ratio was Ar:O₂=99.9:0.1) were introduced, a RF superimposed DC magnetron sputtering method (discharge voltage 150 V, RF frequency 13.56 MHz, and a ratio of RF power to DC power (RF power /DC power) is 0.8) was performed using a sintered object of 10% by weight tin oxide and 90% by weight indium oxide as a target and with a horizontal magnetic field of 100 mT. With such a method, an amorphous transparent conductive layer including an indium-tin composite oxide layer having a thickness of 20 nm was produced. On this amorphous transparent conductive layer, a RF superimposed DC magnetron sputtering method (discharge voltage 150 V, RF frequency 13.56 MHz, a ratio of the RF electric power to the DC electric power (RF electric power /DC electric power) is 0.8) was performed under a vacuum atmosphere (0.40 Pa) in which Ar and O₂ (a flow ratio was Ar:O₂=99.9:0.1) were introduced using a sintered object of 3% by weight tin oxide and 97% by weight indium oxide as a target, and with a horizontal magnetic field 100 mT. With such a method, an amorphous transparent conductive layer including an indium-tin composite oxide layer and having a thickness of 5 nm was produced. The produced transparent conductive film was heated with a 150° C. warm air oven and a crystallizing process was performed.

### Example 2

Except that a single-layered amorphous transparent conductive layer having a thickness of 25 nm was formed using a sintered object of 10% by weight tin oxide and 90% by weight indium oxide as a target. in Example 1, a transparent conductive film was obtained by a process similar to Example 1.

### Example 3

Except that a substrate on which an organic dielectric layer is not formed was used in Example 2, a transparent conductive film was obtained by a process similar to Example 2.

### Example 4

Except that a substrate on which an inorganic dielectric layer was not formed was used in Example 3, a transparent conductive film was obtained by a process similar to Example 3.

### Example 5

Except that the ratio of RF power to DC power in the sputtering (RF power /DC power) was set to 0.4 in Example 4, a transparent conductive film was obtained by a process similar to Example 4.

### Example 6

Except that a film substrate on which an organic dielectric layer having a thickness of 35 nm is formed on a side of one of the faces of a PET film substrate was used, and an amorphous transparent conductive layer was formed with the ratio of RE power to DC power in the sputtering (RE power /DC power) being 0, without superimposing RF, in Example 5, a transparent conductive film was obtained by a process similar to Example 5.

### Example 7

Except that an amorphous transparent conductive layer having a thickness of 20 nm was formed using a sintered object of 3% by weight tin oxide and 97% by weight indium oxide as a target and forming thereon an amorphous transparent conductive layer having a thickness of 5 nm using a sintered object of 10% by weight tin oxide and 90% by weight indium oxide as a target in Example 6, and a transparent conductive film was obtained with a process similar to Example 5.

### Comparative Example 1

Except that DC magnetron sputtering equipment of the normal magnetic field with a horizontal magnetic field of 30 mT was used and the discharge voltage in the sputtering was modified to 430 V in Example 6, a transparent conductive film was obtained similarly to Example 6.

### Comparative Example 2

Except that a DC magnetron sputtering device of the normal magnetic field with a horizontal magnetic field of 30 mT was used and the discharge voltage in the sputtering was modified to 430 V in Example 7, a transparent conductive film was obtained by a process similarly to Example 7.

### Comparative Example 3

Except that the target was changed to an indium-tin composite oxide target (manufactured by Sumitomo Metal Mining Corporation) of a ratio of tin oxide of 3% by weight in Comparative Example 1, a transparent conductive film was obtained by a process similar to Comparative Example 1.

For each of above Examples 1 to 7 and Comparative Examples 1 to 3, a thickness of an amorphous transparent conductive layer after a sputtering process, a carrier density. Hall mobility and a specific resistance of the amorphous transparent conductive layer before a crystallizing process, a carrier density. Hall mobility and a specific resistance of a crystalline transparent conductive layer after the crystallizing process were measured and crystallization was evaluated.

(1) Evaluation of Crystallization

A transparent laminated body including an ITO layer formed on a polymeric film substrate was heated with a hot air oven at 150° C. to undergo a crystallizing process, and immersed in hydrochloric acid of concentration 5% by weight for 15 minutes, and thereafter rinsed with water and dried, and a resistance between terminals with a 15 mm interval was measured with a tester. Herein, in a case where the resistance between the terminals with a 15 mm interval is not excessive of 10 kΩ after immersion into hydrochloric acid, rinsing with water and drying, it was assumed that crystallization of an 110 layer is complete. Also, the measurement described above was carried out every 60 minutes of the heating time, and the time for which completion of crystallization was observed was evaluated as a crystallization time.

(2) Evaluation of Thickness (Film Thickness) of ITO Layer

Using an X-ray reflectivity method as a measurement principle, the thickness of an ITO layer was calculated by measuring an X-ray reflectivity with a powder X-ray cliffractometer (manufactured by Rigaku Corporation, “RINI-2000”) under the following measurement conditions and calculated by analyzing the obtained measurement data with an analyzing software manufactured by Rigaku Corporation, “GXRR3”). The thickness of the ITO layer was analyzed with analysis conditions as indicated below, using a double-layer model including a film substrate and an ITO layer having a density of 7.1 g/cm³, and performing a least square fitting by taking the thickness and the surface roughness of an LEO layer as variables.

### (Measurement Conditions)

Light Source: Cu-Kα ray (wavekngth: 1, 5,418 Å), 40 kV, 40 mA

Optical System: collimated beam optical system

Divergence Slit: 0.05 mm

Light Receiving Slit: 0.05 mm

Monochromatization and Parallelization: multi-layer Coe el mirror

Measurement Mode: θ/2θ scan mode

Measurement Range (2θ): 0.3 to 2.0°

### (Analysis Conditions)

Analytical Method: least square fitting

Measurement Range (2θ): 2θ=0.3 to 2.0°

### (Measuring Method of Carrier Density and Hall Mobility)

Measurement was carried out using a Hall Effect measuring system (manufactured by Bio-Rad Laboratories, Inc., product name “HL5500PC”). The carrier density was calculated using the thickness of the ITO layer obtained by the method described above.

### (Calculation of Length of Motion)

A length of motion L was calculated using the equation described above and the calculated carrier density and Hall mobility after a sputtering process and before an annealing process, and carrier density and Hall mobility after an annealing process.

A surface resistance (Ω/□) of the transparent conductive layer was measured by a four-point probe method in conformity with JIS K7194 (1994). A specific resistance was calculated from the thickness of the ITO layer obtained by the above-mentioned method and the surface resistance. The result of the above evaluation is shown in Table 1.

TABLE 1

| | | | | | | | | SPECIFIC |
|---|---|---|---|---|---|---|---|---|
| | | BEFORE | | AFTER | | | | RESISTANCE OF |
| | THICKNESS OF | CRYSTALLIZATION | | CRYSTALLIZATION | | | CRYSTALLIZA- | CRYSTALLINE |
| | TRANSPARENT | HALL | | HALL | | | TION TIME | TRANSPARENT |
| | CONDUCTIVE | MOBIL- | CARRIER | MOBIL- | CARRIER | LENGTH | BY HEATING | CONDUCTIVE |
| | LAYER | ITY | DENSITY | ITY | DENSITY | OF | AT 150° C. | LAYER |
| | nm | cm²/V · s | E19/cm³ | cm²/V · s | E19/cm³ | MOTION | MINUTES | E-4Ω · cm |
| EXAMPLE 1 | 25 | 23.2 | 47.9 | 36.0 | 124.4 | 77.5 | 60 | 1.4 |
| EXAMPLE 2 | 25 | 23.0 | 47.8 | 34.3 | 126.0 | 79.0 | 120 | 1.4 |
| EXAMPLE 3 | 25 | 21.2 | 47.9 | 30.9 | 123.5 | 76.2 | 120 | 1.6 |
| EXAMPLE 4 | 25 | 17.7 | 37.7 | 27.7 | 117.4 | 80.3 | 120 | 1.9 |
| EXAMPLE 5 | 25 | 12.8 | 37.7 | 23.5 | 117.4 | 80.4 | 120 | 2.3 |
| EXAMPLE 6 | 25 | 17.4 | 32.8 | 28.6 | 94.0 | 62.2 | 120 | 2.3 |
| EXAMPLE 7 | 25 | 17.2 | 40.8 | 24.3 | 114.9 | 74.4 | 60 | 2.2 |
| COMPAR- | 25 | 19.0 | 30.0 | 24.5 | 79.0 | 49.3 | 120 | 3.2 |
| ATIVE | | | | | | | | |
| EXAMPLE 1 | | | | | | | | |
| COMPAR- | 25 | 19.6 | 30.7 | 25.8 | 74.8 | 44.5 | 60 | 3.2 |
| ATIVE | | | | | | | | |
| EXAMPLE 2 | | | | | | | | |
| COMPAR- | 25 | 29.1 | 19.6 | 31.4 | 28.6 | 9.3 | 120 | 7.0 |
| ATIVE | | | | | | | | |
| EXAMPLE 3 | | | | | | | | |

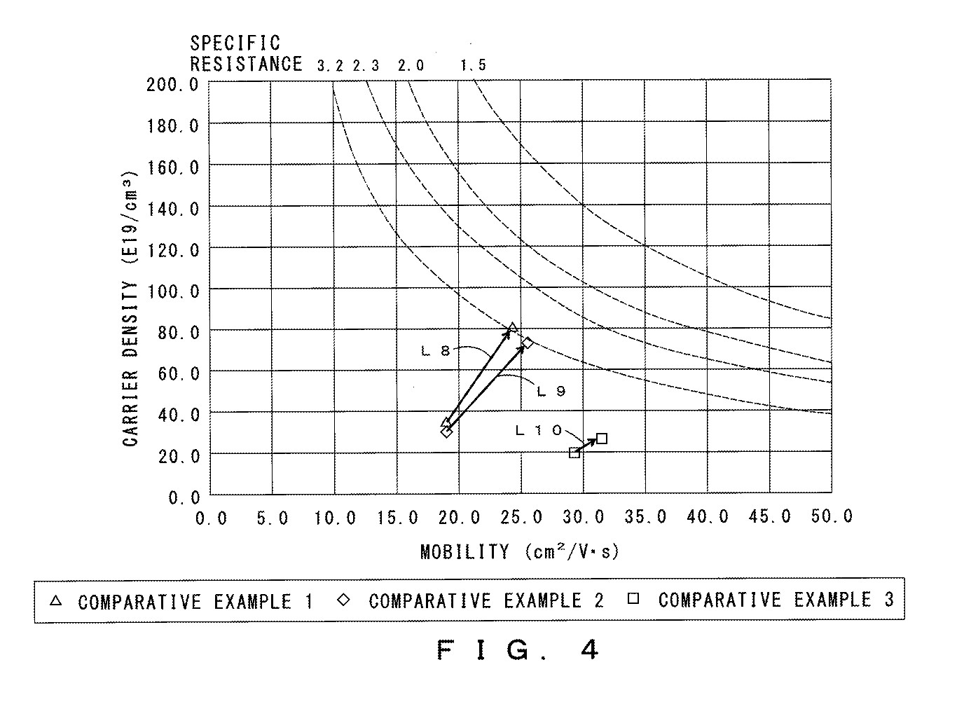

Referring to the results indicated in Table 1, in Example 1, the crystallization time was 60 minutes, which is short, the length of motion L1 was 77.5 (FIG. 3), which is very large, and, the specific resistance was 1.4×10⁻⁴ Ω·cm, which is a very small value, and it can he seen that a conductive film of a low resistance can be obtained with a good productivity. In Example 2, the crystallization time was 120 minutes, which was longer than in Example 1, but the length of motion L2 was 79.0, which is very large, and the specific resistance showed 1.4×10⁻⁴ Ω·cm, which is a very small value, and it can he seen that a conductive film of a low resistance can be obtained, Also, in Example 3, the crystallization time was 120 minutes, but the length of motion L3 was 76.2, which is very large, and the specific resistance showed 1.6×10⁻⁴ Ω·cm, which is greater than those of Examples 1 and 2 but a very small value, and it can be seen that a conductive film of a low resistance can be obtained.

In Example 4, the crystallization time was 120 minutes, but the length of motion L4 was 80.3, which is very large, and the specific resistance showed 1.9 x 10⁻⁴1.2.cm, which is a small value, and it can be seen that a conductive film of a low resistance can be obtained. In Example 5, the crystallization time was 120 minutes, but the length of motion L5 was 80.4, which is ver large, and the specific resistance showed 2.3×10⁻⁴ Ω·cm, which is a relatively small value, and it can be seen that a conductive film of a low resistance can be obtained. In Example 6, the crystallization time was 120 minutes, but the length of motion L6 was 62.2 which is large, and the specific resistance showed 2.3×10⁻⁴ Ω·cm, which is a small value, and it can be seen that a conductive film of a low resistance can be obtained. In Example 7, the crystallization time was 60 minutes, which is short, but the length of motion L7 was 74.4, which is large, and the specific resistance showed 2.2×10⁻⁴ Ω·cm, which is a relatively small value, and it can he seen that a conductive film of a low resistance can be obtained

On the other hand, in Comparative Example 1, the crystallization time was 120 minutes, and the length of motion L8 was 49.3, which is out of range of the present invention (FIG. 4), and the sₚecific resistance showed 3.2×10⁻⁴ Ω·cm, which is a large value. In Comparative Example 2, the crystallization time was 60 minutes, but the length of motion L9 was 44.5, which is out of range of the present invention, and the specific resistance showed 32×10⁻⁴ Ω·cm, which is a large value. In Comparative Example 3, the crystallization time was 120 minutes, and the length of motion L10 was 9.3, which is out of range of the present invention, and the specific resistance showed 7.0×10⁻⁴ Ω·cm which is a large value.

Therefore, by newly defining a length of motion calculated from a Hall mobility and a carrier density just after sputtering and before a crystallizing process by heating, and a Hall mobility and a carrier density after a crystallizing process by heating, and by specifying a range of the length of motion, it was found that a conductive film having a low resistance can be produced effectively.

### INDUSTRIAL APPLICABILITY

The application of the transparent conductive film according the present invention is not particularly limited, and preferably a capacitive touch panel used for portable devices such as smartphones or tablet-type devices (Slate PC).

### LIST OF REFERENCE SIGNS

1 transparent conductive film
2 film substrate
2a main surface
3 transparent conductive layer
4 transparent conductive film
5 transparent conductive layer

1. A transparent conductive film comprising a crystalline transparent conductiNT layer, the crystalline transparent conductive la el being obtained by forming an amorphous transparent conductive layer on a polymeric film substrate by sputtering, the amorphous transparent conductive layer being composed of an indium-tin complex oxide, and performing a crystallizing process on the amorphous transparent conductive layer,
defining that the amorphous transparent conductive layer has a carrier density represented by nₐ×10¹⁹ and Hall mobility represented by μₐ, the crystalline transparent conductive layer has a carrier density represented by n_{c}×10¹⁹ and Hall mobility represented by μ_{c}; and a length of motion L represented by {(n_{c}−nₐ)²+(μ_{c}−μₐ)²}^{1/2},
the amorphous transparent conductive layer before the crystallizing process has a carrier density nₐ×10¹⁹ of (10 to 60)×10¹⁹/cm³ and Hall mobility μₐ of 10 to 25 cm²/V·s,
the crystalline transparent conductive layer after the crystallizing process has a carrier density n_{c}×10¹⁹ of (80 to 150)×10¹⁹/cm³ and Hall mobility μ_{c} of 20 to 40 cm²/V·s, and
the length of motion L is 50 to 150.

2. The transparent conductive film according, to claim 1, wherein the crystallizing process is a process of crystallizing the amorphous transparent conductive layer at a temperature of 110 to 180° C. within 120 minutes.

3. Transparent conductive film according to claim 1, wherein: the amorphous transparent conductive layer has a thickness of 15 am to 40 nm the amorphous transparent conductive layer has a specific resistance of 4.0×10⁻⁴ Ω·cm to 2.0×10⁻³ Ω·cm; and the crystalline transparent conductive layer has a specific resistance of 1.1×10⁻⁴ Ω·cm to 3.0×10⁻⁴ Ω·cm.

4. The transparent conductive film according to claim 1, wherein: the crystalline transparent conductive layer is composed of an indium-tin complex oxide; and a ratio of tin oxid resented by {tin oxide/(indium oxide+tin oxide)}×100 (%) is 0.5% to 15% by weight.

5. The transparent conductive film according to claiin 1, comprising a structure including the crystalline transparent conductive layer and composed of at least two indium-tin complex oxide layers having contents of tin different from each other,
each layer of the at least two indium-tin complex oxide layers being amorphous or crystalline.

6. The transparent conductive film according to claim 5, wherein the at least ilvo layers of indium-tin complex oxide layers has a double-layered structure in which a first indium-tin complex oxide layer and a second indium-tin complex oxide layer are laminated in this order from the polymeric film substrate side,
the first indium-tin complex oxide layer has a tin oxide content of 6% by weight to 15% by weight, and
the second indium-tin complex oxide layer has a tin oxide content of 0.5% by weight to 5.5% by weight.

7. The transparent conductive film according to claim 5, wherein the at least two layers of indium-tin complex oxide layers has a triple-layered structure in which a first indium-tin complex oxide layer, a second indium-tin complex oxide layer and a third indium-tin complex oxide layer are laminated in this order from the polymeric film substrate side,
the first indium-tin complex oxide layer has a tin oxide content of 0.5% by weight to 5.5% by weight,
the second indium-tin complex oxide layer has a tin oxide content by weight to 15% by weight, and
the third indium-tin complex oxide layer has a tin oxide content of 0.5% by weight to 5.5% by weight.

8. The transparent conductive film according to claim 1, wherein an organic dielectric layer formed by a wet film formation method is formed on at least one of the faces of the polymeric film substrate, and
the polymeric film substrate, the organic dielectric layer and the crystalline transparent conductive layer are formed in this order.

9. The transparent conductive film according to claim 1, wherein an inorganic dielectric layer formed by a vacuum film formation method is formed on at least one of the faces of the polymeric filar substrate, and
the polymeric film, the inorganic dielectric layer and the crystalline material transparent conductor layer are formed in this order.

10. Transparent conductive film according to claim 1, wherein an organic dielectric layer formed by a wet film fomiation method and an inorganic dielectric layer formed by a vacuum film formation method are formed on at least one of the faces of the polymeric film substrate, and
the polymeric film, the organic dielectric layer, the inorganic dielectric layer and the crystalline transparent conductor layer are fomied in this order.

11. The transparent conductive film according to claim 1, wherein a material of the polymeric film substrate is selected from a group consisting of polyethylene tereplithalate, polyethylenenaphthalate, polycycloolefin and polycarbonate.

12. A method of manufacturing a transparent conductive layer comprising:
preparing a polymeric film substrate;
forming, on the polymeric film substrate, an amorphous transparent conductive layer composed of amorphous indium-tin complex oxide by RF-superimposed DC magnetron sputtering; and
performing a crystallizing process to crystallize the amorphous transparent conductive layer into a crystalline transparent conductive layer,
defining that the amorphous transparent conductive layer has a carrier density represented by nₐ×10¹⁹ and Hall mobility represented by μₐ, the crystalline transparent conductive layer has a carrier density represented by n_{c}×10¹⁹ and Hall mobility represented μ_{c}; and a length of motion L represented by {(n_{c}−nₐ)²+(μ_{c}−μₐ)²}^{1/2},
the amorphous transparent conductive layer before the crystallizing process has a carrier density nₐ×10¹⁹ of (10 to 60)×10¹⁹/cm³ and Hall mobility μₐ of 10 to 25 cm²/V·s,
the crystalline transparent conductive layer after the crystallizing process has a carrier density n_{c}×10¹⁹ of (80 to 150)×10¹⁹/cm³ and Hall mobility μ_{c} of 20 to 40 cm²/V·s, and
the length of motion L is 50 to 150.

13. The method of manufacturing a transparent conductive film according to claim 12, wherein the crystallizing is a step of crystallizing the amorphous transparent conductive layer at a temperature of 110 to 180° C. within 120 minutes.

14. The method of manufacturing a transparent conductive film according to claim 12, wherein: the amorphous transparent conductive layer has a thickness of 15 nm to 40 nm; the amorphous transparent conductive layer has a specific resistance of 4.0×10⁻⁴ Ω·cm to 2.0×10⁻³ Ω·cm; and the crystalline transparent conductive layer has a specific resistance of 1.1×10⁻⁴ Ω·cm to 3.0×10⁻⁴ Ω·cm.

15. A method of manufacturing a transparent conductive film according to claim 12, wherein: the crystalline transparent conductive layer is composed of an indium-tin complex oxide; and a ratio of tin oxide represented by {tin oxide/(indium oxide+tin oxide)}×100(%) is 0.5% to 15% by weight.

16. The method of inanuficturing a transparent conductive film according to claim 12, comprising a structure including the crystalline transparent conductive layer and composed of at least vo indium-tin complex oxide layers having contents of tin different from each other,
in each layer of the at least two indium-tin complex oxide layers, the indium-tin complex oxide layer is amorphous or crystalline.

17. The method Of manufacturing a transparent conductive: film according to claim 16, wherein the at least two layers of indium-tin complex oxide layers has a double-layered structure in which a first indium-tin complex oxide layer and a second indium-tin complex oxide layer are laminated in this order from the polymeric film substrate side,
the first indium-tin complex oxide layer has a tin oxide content of 6% by weight to 15% by weight, and
the second indium-tin complex oxide layer has a tin oxide content of 0.5% by weight to 5.5% by weight.

18. The method of manufacturing a transparent conductive film according to claim 16, wherein the at least two layers of indium-tin complex oxide layers has a triple-layered structure in which a third indium-tin complex oxide layer is laminated adjacent to a second indium-tin complex oxide layer,
the first indium-tin complex oxide layer has a tin oxide content of 0.5% by weight to 5.5% by weight,
the second indium-tin complex oxide layer has a tin oxide content of 6% by weight to 15% by weight, and
the third indium-tin complex oxide layer has a tin oxide content of 0.5% by weight to 55% by weight.

19. The method of manufacturing a transparent conductive film according to claim 12, wherein an organic dielectric layer formed by a wet film formation method is formed on at least one of the faces of the polymeric film substrate, and
the polymeric film substrate, the organic dielectric layer and the crystalline transparent conductive layer are formed in this order.

20. The method of manufacturing the transparent conductive film according to claim 12, wherein an inorganic dielectric layer formed by a vacuum film formation method is formed on at least one of the faces of the polymeric film substrate, and
the polymeric film, the inorganic dielectric layer and the crystalline transparent conductor layer are formed in this order.

21. The method of manufacturing a transparent conductive fihn according to claim 12, wherein an organic dielectric layer formed by a wet film formation method and an inorganic dielectric layer formed by a vacuum film formation method are formed on at least one of the faces of the polymeric film substrate, and
the polymeric film, the organic dielectric layer, the inorganic dielectric layer and the crystalline iansparent conductor layer are formed in this order.

22. The method of manufacturing a transparent conductive film according to claim 12 wherein a material of the polymeric film substrate is selected from a group consisting of polyethylene terephthalate, polyethylenenaphthalate, polycycloolefin and polycarbonate.
